(19) United States
(12) Patent Application Publication
(10) Pub. No.: US 2012/0255493 A1
(43) Pub. Date: Oct. 11, 2012

(54) GAS EVAPORATOR FOR COATING PLANTS

(75) Inventors: Michael Bauer, Leipzig (DE); Frank Becker, Leipzig (DE); Jochen Frenck, Wolfen (DE); Ingo Dannenberg, Sandersdorf-Brehna OT Petersroda (DE); Michael Schlauch, Leipzig (DE); Thomas Etzrodt, Bitterfeld-Wolfen OT Thalheim (DE); John Bohland, Folsom, CA (US); Jonas Knothe, Halle (DE)

(73) Assignee: Calyxo GMBH, Bitterfeld-Wolfen (DE)

(21) Appl. No.: 13/502,190

(22) PCT Filed: Oct. 12, 2010
(86) PCT No.: PCT/EP10/06210

§ 371 Date: Jun. 18, 2012

(30) Foreign Application Priority Data
Oct. 16, 2009 (DE) 10 2009 049 839.7

(51) Int. Cl. C23C 16/448; F25B 29/00

(52) U.S. Cl. 118/724; 118/726; 165/58

(57) ABSTRACT

The present invention relates to gas evaporator devices (1) and methods for operating them. By virtue of the improvements according to the invention, the service life of conventional gas evaporator devices can be significantly improved, such that the maintenance and material outlay and hence the costs of the coating method are reduced. This is achieved by virtue of the fact that a shielding element (5) impermeable at least to passage of the material is provided at least between the mixture of gas and material flowing in the section (4), in which material to be evaporated is guided in a gas flow and is heated by the heating element (2), and the heating element (2).

The present invention relates to an evaporator device for coating installations in accordance with the preamble of Claim 1.

Such evaporator devices are based on the principle of thermal evaporation and thus utilize a very simple evaporation method for the coating technique. In thermal evaporation, in contrast to alternative methods such as electron beam evaporation, laser beam evaporation or arc evaporation, the material to be evaporated is heated to temperatures above the boiling point. The heating is effected by means of a heating element, resistance heaters generally being used. The evaporated material deposits on a generally cooled substrate and forms a thin layer there as a result of condensation.

Primarily in the context of APCVD (atmospheric pressure chemical vapour deposition) it is already known to use gas evaporator devices in which, in a gas guide line, material to be evaporated is guided in a gas flow and is heated by the heating element. The emerging gas flow can then be directed onto the substrate in a highly targeted manner.

Such gas evaporator devices have to be designed for very high temperatures. Moreover, very high gas flow rates are necessary since atmospheric pressure is employed in APCVD. For this reason, a very large heat exchanger is necessary in order that the large quantities of gas guided through the gas evaporator device can be heated to the high temperatures before they emerge from the gas evaporator device. Such gas evaporator devices therefore constitute very large components.

Such gas evaporator devices usually consist of a resistance heater composed of doped silicon carbide and the gas guide line is generally produced from undoped silicon carbide.

The gas evaporator device is operated by a pulverulent material to be evaporated being guided in a gas flow, preferably in an inert gas, such as e.g. nitrogen, through the gas guide line and the heating element simultaneously being operated. As a result of the electromagnetic radiation emitted by the heating element, heating of the gas guide line is brought about by thermal radiation and absorption in the gas guide line formed, for example, from undoped silicon carbide. The gas guide line then passes on heat to the material-gas flow by way of convection, as a result of which the pulverulent material is heated and evaporated upon reaching the melting point. If the heating power, length of the gas guide line and quantity of the material to be evaporated are suitably coordinated with one another, then the material introduced into the gas evaporator device is evaporated completely and in the necessary quantities and is available for coating processes.

The gas evaporator device required for this purpose is—as stated—generally very large; specifically, by way of example, it is constructed in a cylindrical fashion and has a diameter of approximately 0.5 m to 0.7 m and a length of approximately 1.5 m to 2 m. In order that the gas guide line nevertheless has a sufficient length, it is led in a multiply folded fashion over the length of the gas evaporator device, that is to say that it is led in a plurality of sections parallel to the longitudinal extent of the gas evaporator device and deflected by 180 degrees at the lateral ends of the gas evaporator device. A pipe bundle that is used is therefore involved.

Usually approximately 400 l/min of cold and 1 200 to 1 600 l/min of hot gas flow are conducted through such a gas evaporator device and the temperatures of the gas guide line are generally between 1 000° C. and 1 400° C.

What is disadvantageous about such known gas evaporator devices is that the latter have only a relatively short service life, which is generally between 12 hours and days. After this time the entire gas evaporator device has to be replaced since it becomes unusable. This is associated with a high material outlay but also a high maintenance outlay, this being manifested in increased costs of the coating method.

It is an object of the present invention, therefore, to specify a gas evaporator device and also a method for operating the latter which enables increased service lives with the same evaporator performance, such that the material and maintenance outlay can be reduced.

This object is achieved by means of an evaporator device according to Claim 1 and a method for operating an evaporator device according to Claim 14.

The invention is based on the surprising insight for a person skilled in the art that the cause of the limitation of the service life of the conventional gas evaporator devices stems from a permeability of the gas guide line primarily to passage of material. This is owing to the fact that gas guide lines are principally produced from silicon carbide. Silicon carbide as material, however, itself already has certain leaks, such that material can emerge from the gas guide line.

Moreover, gas evaporator devices used on an industrial scale require very great lengths for the gas guide line, for example 10 to 12 m, a distance of approximately 4 m being required for heating 400 l/min of nitrogen in the gas guide line to a temperature of greater than 1 000° C. As a result of this, great heat differences occur within the gas guide line, these differences leading to stresses. These stresses firstly have the consequence that monolithic silicon carbide can crack. Secondly, the stress brings about a tilting of the cover of the gas evaporator device, in which cover the 180° deflections of the gas line bundle are performed, as a result of which likewise fracture locations occur and leaks are produced. Finally, the strains and tilting also adversely affect the slip, ceramic adhesive or cement which is used for bonding individual monolithic silicon carbide parts, and in which cracks can arise, such that further leaks arise.

The inventors have now recognized that this emerging pulverulent material or evaporated material limits the service life of the industrial-scale gas evaporator device by virtue of the fact that plasmas can form within the gas evaporator device. This can occur, on the one hand, within the resistance heater, which usually consists of doped silicon carbide that is guided in the form of a double helix. At the location at which the resistance heater is supplied with current, a very high potential difference occurs on account of the double helix structure. As a result of material entering there, a plasma can therefore be ignited very easily. On the other hand, such a plasma can, of course, also be ignited between the resistance heater and the gas guide line. This takes place because the non-doped silicon carbide used for the gas guide line becomes conductive in an ohmic fashion at temperatures starting from approximately 1 000° C. Therefore, a short circuit can also take place here as a result of plasma formation.

Independently of that, of course, the system-governed oscillations of the coating installation can also lead to contacts between the current-carrying heater and the gas guide line that is conductive above 1 000° C.

The solution according to the invention consists in an evaporator device for coating installations comprising a heating element and a gas guide line, the gas guide line having a section in which material to be evaporated is guided in a gas flow and is heated by the heating element, wherein a shielding element impermeable at least to passage of the material is provided at least between the mixture of gas and material flowing in the section and the heating element.

The inventors have thereby eliminated the disadvantageous effect of the emergence of material from the gas guide system and crossover of material into the heating system in conventional gas evaporator devices, such that the service lives have been able to be significantly increased to greater than 12 days or more. As a result, the coating process is no longer limited by the service life of the gas evaporator device, but rather by other components, as a result of which the maintenance and material costs can be significantly reduced.

In one particularly advantageous configuration, the shielding element is provided between the section and the heating element and, in particular, extends in an enclosing fashion around the heating element in an axial direction of the gas evaporation device. As a result, the heating element is sheathed in a condom-like manner, such that plasma ignitions are effectively prevented. In addition, thermal separation and hence also homogenization between the regions of heating element and heat exchanger (gas guide line) is effected. Finally, mechanical separation is also effected, which prevents oscillation-governed short circuits.

It is advantageous if the shielding element absorbs substantially no thermal radiation; the heating element can then be operated with the same power in order to obtain the same heat input into the heat exchanger. However, alternatively provision can also be made for the shielding element to absorb thermal radiation. This is advantageous primarily when the heating element is not configured sufficiently homogeneously and so-called “hotspots” arise as a result of doping inhomogeneities, for example. By means of the shielding element which is absorbent and thus also emits thermal radiation again, the thermal radiation is then homogenized in the same manner as is done, for instance, by a lampshade with regard to an incandescent lamp.

The shielding element is expediently provided with a cooling system, such that the thermal loading of the shielding element can be kept small. This is advantageous, in particular, when the shielding element consists of quartz glass, which becomes soft at high temperatures. Moreover, a transformation into a polycrystalline phase takes place in the quartz glass at temperatures of approximately 1200° C., as a result of which absorption occurs. A cooling system prevents this transformation, such that the quartz glass remains absorption-free.

In a further particularly advantageous configuration, the shielding element, at least in the section, forms the gas guide line and is designed at least partly to absorb electromagnetic radiation. As a result, the hitherto conventional undoped silicon carbide is replaced by a shielding element that is non-transmissive to the coating material, as a result of which the formation of plasmas is also prevented. Particularly when the shielding element then consists of a material that is insulating even at high temperatures, for example quartz glass, short circuits on account of mechanical loading are once again also very effectively avoided.

Of course, the replacement of the gas guide line in the section by the shielding element can also be associated with a shielding element which is to be provided in addition and which is arranged between the heating element and the gas guide line and surrounds the heating element in an axially sheathing, condom-like manner.

In an additionally particularly preferred configuration the gas guide line, at least in the section, is embodied spirally around the longitudinal orientation of the evaporator device and the heating element is preferably arranged in the interior of the spiral. As a result, the Nusselt number can be reduced, thereby improving the heat transfer into the gas flow as a result of convection on account of a reduced boundary layer. This is probably owing to the fact that, by comparison with the laminar gas guidance in the conventional straight gas guide in the pipe bundles, turbulent flows now occur on account of centrifugal forces that occur in the spiral gas guide, said turbulent flows increasing the heat convection.

Furthermore the spiral is fixedly connected by leadthroughs to the housing of the gas evaporation device only at two points, while the pipe bundle of conventional gas evaporation devices has fixed leadthroughs in the housing covers at the multiplicity of deflection points. As a result, according to the invention, thermally governed stresses in the gas evaporator device are minimized, such that no stress-governed leaks occur. Moreover, a glass spiral, for example, can be constructed monolithically in a particularly simple and cost-effective manner, which also eliminates the risk of leakage since there are no joints with slip or the like.

Particularly if the shielding element becomes unstable at high temperatures, it is advantageous for the evaporator device to have a housing and between shielding element and housing an in particular thermally insulating supporting structure to be arranged for the purpose of holding the shielding element, the supporting structure preferably comprising a cured slip. This is expedient primarily when the gas guide line itself is embodied as a shielding element and is formed from quartz glass, in particular.

It is particularly expedient if the shielding element is embodied such that it is also impermeable to passage of the gas; gas-governed corrosion, particularly when non-inert gases are used, is then prevented. On the other hand, APCVD gas evaporation devices are designed for operation in an oxygen atmosphere. In this case, introduction of nitrogen, for example, from the gas flow into the heating element is disadvantageous and shortens the service life, such that advantages of this gas-tight shielding are also afforded in the case of inert gases.

It is highly advantageous if the shielding element comprises a glass, in particular a quartz glass, or a glass ceramic, since said glass has an electrically insulating effect. Moreover, glass is particularly cost-effective relative to silicon carbide. If the glass as shielding element in the section forms the gas guide line itself, then it should preferably be embodied as absorbent for thermal radiation in order to enable the emission of heat by convection to the gas flow. The glass should expediently be embodied in an opaque fashion, for example. In the case where the glass shielding element forms the gas guide line itself, any risk of contamination which exists in the case of silicon carbide and leads to impurities in the coating material is also advantageously eliminated.

The shielding element is expediently embodied in a tubular fashion.

Preferably, the heating element is a resistance heater and advantageously comprises doped silicon carbide.

An APCVD gas evaporator device is advantageously intended to be involved, that is to say an evaporator device which is designed to be arranged in a reaction-free manner in an oxygen atmosphere and to be operated with nitrogen as gas and preferably with one of the substances of main group II, VI or subgroup II of the periodic table of the elements or a mixture thereof.

Independent protection is claimed for a first preferred method for operating the evaporator device according to the invention wherein the shielding element is cooled in order to prevent the absorption of thermal radiation from increasing in a manner governed by phase transformation, and/or in that the power of the heating element is adapted in such a way as to compensate for a loss of heat transmission as a result of the shielding element. Therefore, firstly, the intention is to prevent the shielding element that surrounds the heating element in a condom-like manner from absorbing thermal radiation and, secondly, the intention is to compensate for absorptions that occur, if appropriate, by increasing the heating power, such that the heat input into the gas flow reaches the necessary value in order to evaporate the required quantity of material.

In addition, independent protection is claimed for a second preferred method for operating the evaporator device according to the invention, wherein cooling of the shielding element below a phase transformation temperature is prevented after the initial operation of the evaporator device. As a result, particularly in the case of shielding elements composed of glass, the situation is prevented in which, after transformation into the polycrystalline phase, as a result of cooling, said shielding elements again undergo a phase transformation, which brings about stresses, and they can lead to the cracking of the shielding element, this lower temperature being approximately 300° C. This method, can, of course, also be used in combination with the first method according to the invention.

The features and characteristics of the present invention and also further advantages will become clear below from the description of two preferred exemplary embodiments with reference to the figures in which:

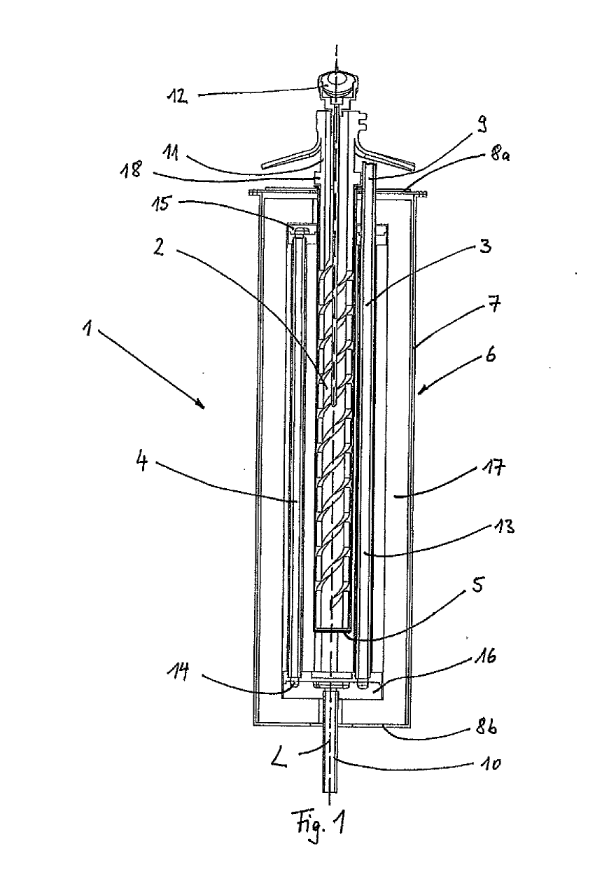

FIG. 1 shows a first preferred embodiment of the evaporator device according to the invention, and

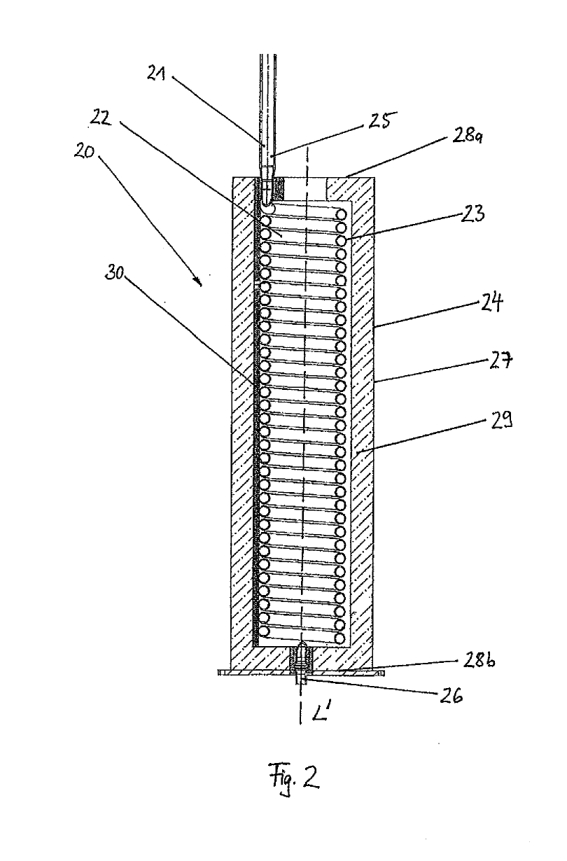

FIG. 2 shows a second preferred embodiment of the evaporator device according to the invention.

A first preferred configuration of the evaporator device 1 according to the invention is used purely schematically in section in FIG. 1. The evaporator device 1 has a heating element 2 and a gas guide line 3. Furthermore, a shielding element 5 is arranged between the section 4 of the gas guide line 3, in which the gas-material flow guided through the gas guide line 3 is heated by means of the heating element 2, and the heating element.

The housing 6 of the evaporator device 1 has a hollow cylindrical section 7 and two covers 8a, 8b closing off the latter. The housing 6 is penetrated by the sections 9 and 10 of the gas guide line 3 and the connection 11 of the heating element 2. The connection 11 in turn has an electrical supply connection 12.

The section 4 of the gas guide line 3 in the interior of the housing 6 has, along the longitudinal extent L of the evaporator device 1, straight sections 13 and deflections 14 by 180°, the deflections 14 preferably being arranged in uniform plates 15, 16. The heating element 2 is embodied as a double helix and consists of doped silicon carbide, while the housing 6 consists of steel, high-grade steel or the like and the gas guide line 3 consists of undoped silicon carbide. A thermal insulation 17 composed of aluminum oxide is provided between housing 6 and gas guide line 3. In this case, the shielding element 5 extends in a condom-like manner proceeding from the upper cover 8a and encloses the heating element 2 both with regard to the circumference along the longitudinal extent L and radially in the region of the lower cover 8b.

During the operation of the evaporator device 1, an inert gas flow, for example nitrogen, is introduced into the evaporator device through the section 9 and material to be evaporated is situated in the gas flow, said material preferably being entrained in pulverulent form in the gas flow. The material preferably comprises one or more elements or a mixture thereof composed of substances of main group II, VI or subgroup II of the periodic table of the elements, for example CdTe or TdS.

The cold gas flow of approximately 400 l/min is introduced through section 9 and is subsequently guided past along the heating element 2 multiply in the interior of the housing 6 through the section 4 of the gas guide line 3 and is progressively heated along the section 4 by virtue of the fact that the thermal radiation emitted by the heating element 2 is absorbed by the undoped silicon carbide in the section 4 and is transferred to the gas-material flow by means of heat convection. The section 4 therefore forms a heat exchanger. After a length of the section 4 of approximately 4 meters, the gas-material mixture reaches a temperature of above 1 000° C., as a result of which the material evaporates and then, in the section 9 of the gas guide line 3, can be made available from the evaporator device 1 to a coating process in a targeted manner. The gas flow in the heated state is approximately 1 200 to 1 600 l/min.

The section 4 of the gas guide line 3 in the interior of the housing 6 of the evaporator device 1 is embodied as a pipe bundle consisting of monolithic straight sections 13 and the deflection sections 14 arranged into the plates 15, 16. In this case, the sections 13 and 14 are joined together by slip, a ceramic adhesive or cement. On account of the firstly gradual heat input into the gas-material flow, a temperature gradient builds up along the section 4. Said temperature gradient has the effect, firstly, that leaks in the joints between the sections 13 and 14 that are formed by slip, ceramic adhesive or cement can arise as a result of stresses and, furthermore, warpages and hence cracks and leaks can also additionally arise as a result of leverage on the covers 8a, 8b. Moreover, the silicon carbide of the gas guide line 3 itself is also not absolutely impermeable to passage of the material entrained in the gas flow and of the gas.

However, the shielding element 5 effectively prevents the crossover of such material from the section 4 into the region of the heating element 2. As a result, plasma ignitions and hence short circuits cannot occur within the heating element and, moreover, plasma ignitions are also prevented between the section 4 and the heating element since otherwise the undoped silicon carbide of the section 4 becomes conductive at temperatures of around 1 000° C. and plasmas can likewise occur there.

The shielding element 5 consists of a quartz glass connected to the cover 8a of the housing 6 in a gas-tight manner at the mount 18. The mount can comprise a support which is composed of aluminum oxide and which serves for both sealing and mechanical damping. The quartz glass itself is impermeable both to the passage of material and to the passage of gas and is furthermore also electrically insulating, such that mechanically governed short circuits are also prevented and gas-governed corrosion of the heating element 2 is prevented.

Preferably the shielding element 5 is embodied such that it is transparent to thermal radiation and is cooled (not shown), such that the transformation point to the polycrystalline phase at approximately 1 200° C. is not reached even with intensive heating power. Therefore, the shielding element 5 remains transparent even at high heating powers and there is no need to adapt the heating power to the radiation losses as a result of the shielding element. Moreover, a renewed phase transformation which can otherwise lead to cracking of the shielding element 5 as a result of stresses is thereby prevented upon cooling of the shielding element 5 after the heating element 2 has been turned off.

Alternatively, however, provision can also be made for the shielding element 5 to be designed as absorbent for thermal radiation in a targeted manner. This brings about a homogenization of the thermal radiation of the heating element 2 in a manner similar to a lampshade and thereby compensates for hotspots brought about by inhomogeneous doping of the silicon carbide heating element 2. In this case, the heat absorption of the shielding element 5 can either be set in a targeted manner by virtue of the shielding element 5 consisting of an opaque quartz glass, for example, or the shielding element 5 is not cooled, such that, in the quartz glass, a phase transformation to the polycrystalline structure takes place, which has a heat-absorbing effect. In this case, however, it should preferably be provided that the shielding element 5 no longer cools below a lower phase transformation temperature of approximately 300° C., at which the structure of the quartz glass changes from polycrystalline to amorphous since this would once again introduce stresses that would lead to cracking of the shielding element 5, as a result of which the service life of the evaporator device 1 would once again be limited to a greater extent.

A second preferred configuration of the evaporator device 20 according to the invention is illustrated purely schematically in section in FIG. 2. The evaporator device 20 once again has the heating element illustrated in FIG. 1, that said heating element is not shown here for the sake of clarity. Furthermore, the evaporator device 20 has a gas guide line 21 comprising a section 22, formed by the shielding element 23 itself, in the interior of the housing 24 and two leadthrough sections 25 and 26. The housing 24 consists of a hollow cylinder section 27 and two cover sections 28a, 28b, the feeding section 25 of the gas guide line 21 and the connection of the heating element being led through the first cover section 28a and only the exit 26 of the gas guide line 21 being led through the second cover section 28b. A thermal insulation 29 composed of aluminum oxide or the like is once again provided between housing 24 and gas guide line 21.

The section 22 of the gas guide line 21 in the interior of the housing 24 is arranged along the longitudinal extent L′ of the evaporator device 20 spirally around said longitudinal extent L′ and hence also around the heating element and consists of a quartz glass which absorbs thermal radiation and which is preferably embodied in an opaque fashion. This section 22 is connected to the housing 24 via the thermal insulation 29 with a slip (e.g. silicon oxide or aluminum oxide) or the like as supporting structure 30 in order to stabilize the heat exchanger 22, such that any temperature-governed deviation of the quartz glass that possibly occurs is absorbed by the supporting structure 30. On account of the spiral structure of the section 22, no strains can occur in the longitudinal extent L′, such that no leaks can originate therefrom. In addition, the quartz glass, which in the section 22 forms the gas guide line 21 itself, prevents any emergence of gas and material from the gas guide line 21 into the region of the heating element. Therefore, no plasma-governed short circuits can occur in the evaporation device 20. Moreover, the quartz glass itself is electrically insulating, such that no mechanically governed short circuits occur either. The service life of this evaporator device 20 according to the invention is therefore likewise significantly increased by comparison with that of conventional evaporator devices.

Quartz glass itself is a poorer heat conductor than silicon carbide. By virtue of the configuration according to the invention of the section 22 as a spiral form, however, the Nusselt number is significantly reduced, such that the heat convection is increased. This leads to a compensation of the poorer heat conduction, as a result of which, in the evaporator device 20, higher heating powers are not required in order to evaporate an identical quantity of coating material. In addition, the evaporator performance can additionally be increased by the spiral of the section 22 being led very closely. This is not readily possible in the case of the conventional bundle-type guide in accordance with FIG. 1 and, as a result, the thermal radiation of the heating element is utilized significantly more effectively and, moreover, the length of the section 22 is increased to approximately 15 m, such that overall more material can be evaporated. Alternatively, of course, whilst maintaining the quantity of material to be evaporated, the dimensioning of the evaporator device 20 can be reduced by comparison with the dimensioning of the evaporator device 1.

Since opaque glass is generally obtainable with a diameter of approximately 2 cm instead of the conventional diameter of approximately 2.5 cm for silicon carbide, the flow velocity in the heat exchanger 22 in FIG. 2 is higher than in the heat exchanger 4 in FIG. 1. As a result, the flow likewise becomes more turbulent and the boundary layer becomes smaller, which further reduces the Nusselt number. A smaller diameter of the heat exchanger 22 therefore increases the heat convection, but the flow velocity is also increased, such that the length of the heat exchanger 22 has to be increased in order that, at the end of the heat exchanger, the same temperature of the gas-material mixture is present and the same quantity of material is evaporated.

In the evaporator device 20 it is not necessary to provide an additional shielding element between the section 22 and the heating element but this can advantageously be done when thermal homogenization by means of such an additional shielding element that absorbs thermal radiation is desirable.

It is thus clear that individual or a plurality of features of the evaporator device according to the invention can be used by themselves or advantageously in combination with one another. The methods according to the invention for operating the evaporator device according to the invention in turn make an additional contribution to increasing the service lives of such evaporator devices.

It has become clear from the above that with the present invention processes with gas evaporation can be carried out significantly more efficiently since, with the same evaporator performance, longer service lives of the evaporator devices 1, 20 by comparison with conventional evaporator devices are made possible, such that material and maintenance outlay in the process and hence the costs thereof are reduced.

1. Evaporator device (1; 20) for coating installations comprising a heating element (2) and a gas guide line (3; 21), the gas guide line (3; 21) having a section (4; 22) in which material to be evaporated is guided in a gas flow and is heated by the heating element (2), characterized in that a shielding element (5; 23) impermeable at least to passage of the material is provided at least between the mixture of gas and material flowing in the section (4; 22) and the heating element (2).

2. Evaporator device (1) according to claim 1, characterized in that the shielding element (5) is provided between the section (4) and the heating element (2), in particular extends in an enclosing fashion around the heating element (2) in an axial direction (1). 20

3. Evaporator device according to claim 1 or 2, characterized in that the shielding element (5) absorbs substantially no thermal radiation.

4. Evaporator device according to any of the preceding claims, characterized in that the shielding element (5) is provided with a cooling system.

5. Evaporator device (20) according to claim 1, characterized in that the shielding element (23), at least in the section (22), forms the gas guide line (21) and is designed at least partly to absorb electromagnetic radiation.

6. Evaporator device according to any of the preceding claims, characterized in that the gas guide line (21), at least in the section (22), is embodied spirally around the longitudinal orientation of the evaporator device (L′) and the heating element (2) is preferably arranged in the interior of the spiral.

7. Evaporator device according to any of the preceding claims, characterized in that the evaporator device has a housing (24) and between shielding element (23) and housing (24) an in particular thermally insulating supporting structure (29) is arranged for the purpose of holding the shielding element (23), the supporting structure (29) preferably comprising a cured slip.

8. Evaporator device (1; 20) according to any of the preceding claims, characterized in that the shielding element (5; 23) is embodied such that it is also impermeable to passage of the gas.

9. Evaporator device (1; 20) according to any of the preceding claims, characterized in that the shielding element (5; 23) comprises a glass, in particular a quartz glass, or glass ceramic, the shielding element (23) preferably being embodied such that it absorbs thermal radiation, in particular such that it is opaque.

10. Evaporator device (1; 20) according to any of the preceding claims, characterized in that the shielding element (5; 23) is embodied in a tubular fashion.

11. Evaporator device (1; 20) according to any of the preceding claims, characterized in that the heating element (2) is a resistance heater.

12. Evaporator device (1; 20) according to any of the preceding claims, characterized in that the heating element (2) comprises doped silicon carbide.

13. Evaporator device (1; 20) according to any of the preceding claims, characterized in that said evaporator device is designed to be arranged in a reaction-free manner in an oxygen atmosphere and to be operated with nitrogen as gas and preferably with one of the substances of main group II, VI or subgroup II of the periodic table of the elements or a mixture thereof.

14. Method for operating an evaporator device (1) according to any of the preceding claims, characterized in that the shielding element (5) is cooled in order to prevent the absorption of thermal radiation from increasing in a manner governed by phase transformation, and/or in that the power of the heating element (2) is adapted in such a way as to compensate for a loss of heat transmission as a result of the shielding element (5).

15. Method for operating an evaporator device (I) according to any of claims 1 to 13 and in particular according to claim 14, characterized in that cooling of the shielding element (5) below a phase transformation temperature is prevented after the initial operation of the evaporator device (1).
